(19) United States
(12) Patent Application Publication
(10) Pub. No.: US 2008/0236650 A1
(43) Pub. Date: Oct. 2, 2008

(54) Method and system for manufacturing solar panels using an integrated solar cell using a plurality of photovoltaic regions

(75) Inventors: Kevin R. Gibson, Redwood City, CA (US); Alelie T. Funcell, Fremont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Solaria Corporation, Fremont, CA (US)

(21) Appl. No.: 12/136,581

(22) Filed: Jun. 10, 2008

Related U.S. Application Data
(62) Division of application No. 11/493,380, filed on Jul. 25, 2006.
(60) Provisional application No. 60/702,728, filed on Jul. 26, 2005.

(51) Int. Cl. H01L 31/042; H01R 43/00

(52) U.S. Cl. 136/244; 29/854

(57) ABSTRACT

A solar panel apparatus and method. The apparatus has an optically transparent member comprising a predetermined thickness and an aperture surface region. The apparatus has a solar cell coupled to a portion of the optically transparent member. In a specific embodiment, the solar cell includes a transparent polymeric member and a plurality of photovoltaic regions provided within a portion of the transparent polymeric member. In a specific embodiment, the plurality of photovoltaic regions occupies at least about 10 percent of the aperture surface region of the transparent polymeric member and less than about 80% of the aperture surface region of the transparent polymeric member.

### CROSS-REFERENCES TO RELATED APPLICATIONS

This application is a divisional of U.S. application Ser. No. 11/493,380 filed Jul. 25, 2006, which claims priority to U.S. Provisional Application Ser. No. 60/702,728 filed Jul. 26, 2005, commonly assigned, hereby incorporate by reference for all purpose.

### BACKGROUND OF THE INVENTION

The present invention relates generally to solar energy techniques. More particularly, the present invention provides a method and resulting solar panel apparatus fabricated from a solar cell including a plurality of photovoltaic regions provided within one or more substrate members. Merely by way of example, the invention has been applied to a solar cell including the plurality of photovoltaic regions, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable.

### BRIEF SUMMARY OF THE INVENTION

According to the present invention, techniques related to solar energy are provided. More particularly, the present invention provides a method and resulting solar panel apparatus fabricated from a solar cell including a plurality of photovoltaic regions provided within one or more substrate members. Merely by way of example, the invention has been applied to a solar cell including the plurality of photovoltaic regions, but it would be recognized that the invention has a much broader range of applicability.

In a specific embodiment, the present invention provides a method for manufacturing a solar panel. Preferably, the solar panel can be ready to be installed onto a physical structure, e.g., house, building, warehouse, automobile, truck, ground, or any other fixed and/or movable entities. The method includes providing a solar cell, which has a transparent polymeric member. Preferably, the transparent polymeric member comprises a plurality of photovoltaic regions, which may be a plurality of strips or other shapes, depending upon the specific embodiment. An example of a solar cell has been described in U.S. Ser. Nos. 11/445,933 and 11/445,948 (corresponding respectively to Attorney Docket Nos. 025902-0002100US and 025902-000220US) filed Jun. 2, 2006, which claims priority to U.S. Provisional Patent Ser. No. 60/688,077 filed Jun. 6, 2005 (Attorney Docket No. 025902-000200US), in the name of Kevin R. Gibson, commonly assigned, and hereby incorporated by reference for all purposes. In a specific embodiment, the plurality of photovoltaic regions occupies at least about 10% of an aperture surface region of the transparent polymeric member and up to about 80% of the aperture surface region of the transparent polymeric member. The method includes coupling the solar cell to an optically transparent member (e.g., solid, optically transparent, mechanically rigid, member having a heat deflection temperature of 100 Degrees Celsius and greater, which may be a thermo plastic or glass member or members) to form a solar panel. The optically transparent member has a predetermined thickness and surface region. In a specific embodiment, the predetermined thickness provides a mechanical structure to support the solar cell thereon.

In an alternative specific embodiment, the invention provides a solar panel apparatus. The apparatus has an optically transparent member comprising a predetermined thickness and an aperture surface region. The apparatus has a solar cell coupled to a portion of the optically transparent member. In a specific embodiment, the solar cell includes a transparent polymeric member (e.g., solid, optically transparent, mechanically rigid, member having a heat deflection temperature of 100 Degrees Celsius and greater, which may be a thermo plastic or glass member or members) and a plurality of photovoltaic regions provided within a portion of the transparent polymeric member. In a specific embodiment, the plurality of photovoltaic regions occupies at least about 10 percent of the aperture surface region of the transparent polymeric member and less than about 80% of the aperture surface region of the transparent polymeric member.

In an alternative specific embodiment, the present invention provides a method for manufacturing a solar panel. The method includes providing a plurality of solar cells. Each of the solar cell comprises a transparent polymeric member, which has a plurality of photovoltaic regions. In a preferred embodiment, the plurality of photovoltaic regions occupies at least about 10% of an aperture surface region of the transparent polymeric member and up to about 80% of the aperture surface region of the transparent polymeric member. The method includes aligning each of the solar cells in a spatial configuration on a surface of an optical transparent member. The method also includes coupling the plurality of solar cells to the optically transparent member to form a solar panel. The optically transparent member has a predetermined thickness and surface region. The predetermined thickness provides a mechanical structure to support each of the solar cells thereon.

In a specific embodiment, the present invention provides a method for manufacturing a solar panel using a low temperature thermal treatment process, which has a temperature characteristic of less than 150 Degrees Celsius. The method includes providing a solar cell, which has been packaged using polymeric materials. That is, the solar cell has a transparent polymeric member, including a plurality of photovoltaic regions coupled to the transparent polymeric member. In a specific embodiment, the plurality of photovoltaic regions occupies at least about 10% of an aperture surface region of the transparent polymeric member and up to about 80% of the aperture surface region of the transparent polymeric member. In a specific embodiment, the transparent polymeric member has a surface region, the surface region being substantially flat and uniform. In a specific embodiment, the method also includes aligning the surface region of the transparent polymeric member of the solar cell to an optically transparent glass member to form an interface region between the surface region and a glass surface region of the transparent glass member. The optically transparent member has a predetermined thickness and surface region according to a specific embodiment. In preferred embodiments, the predetermined thickness provides a mechanical structure to support the solar cell thereon. In a specific embodiment, the method also includes applying force (e.g., mechanical) on either or both the transparent glass member and the transparent polymeric member to cause an increase in pressure at the interface region to change from a first state to a second state. The method includes processing at least the interface region using a thermal process to form a laminated sandwiched structure including the transparent glass member and the transparent polymeric member and cause the interface region to change from the second state to a third state. In a specific embodiment, the method maintains the thermal process at a temperature below about 150 Degrees Celsius to cause formation of the laminated structure and cause the interface region to be substantially free from one or more substantial voids in the third state.

In alternative embodiments, the method in combination of the above also applies a vacuum on at least the interface region to cause the interface region to be substantially free from voids concurrent with the thermal treatment. Of course, there can be other variations, modifications, and alternatives. As used herein and throughout the specification, the term “state” including, but not limited to first state, second state, third state, or other states should be interpreted by its ordinary meaning. That is, the state can be a liquid, gas, fluid, solid, combinations of these, and the like. Alternatively, the state can be a laminated, non-laminated, or other states according to a specific embodiment. In a specific embodiment, the term state can include one or more voids or be free of one or more voids. The term “state” can also refer to a permanent state, temporal state, or any transitory or transitional states, including any combinations of these. Of course, there can be other variations, modifications, and alternatives.

Still further, the present invention provides a method for manufacturing an alternative solar panel and/or module. The method includes providing a sealed solar cell, which has a transparent polymeric member in a specific embodiment. The transparent polymeric member has one or more photovoltaic regions coupled to the transparent polymeric member. In a specific embodiment, the one or more photovoltaic regions occupies at least about 10% of an aperture surface region of the transparent polymeric member and up to about 100% of the aperture surface region of the transparent polymeric member. The transparent polymeric member has a surface region, which is substantially flat and uniform. The one or more photovoltaic regions is first sealed between the transparent polymeric member and a backside member. Depending upon the embodiment, sealing the covers together occurs using a variety of suitable techniques such as ultrasonic welding, vibrational welding, thermal processes, chemical processes, a glue material, an irradiation process (e.g., laser, heat lamp), any combination of these, and others. In a specific embodiment, the sealing technique uses a laser light source called IRAM 200 and 300 manufactured by Branson Ultrasonics Corporation, but can be others. Of course, there can be other variations, modifications and alternatives.

Further to the above embodiment, the method includes providing a coupling material overlying the surface region of the transparent polymeric member. The method includes providing an encapsulating material overlying the backside member according to a specific embodiment. In one or more embodiments, the coupling material and encapsulating material are the same material, which are provided in separate portions. In a specific embodiment, the method includes processing the coupling material and encapsulating material to form a second seal encapsulating the solar cell including the one or more of photovoltaic regions and cause formation of a laminated structure including the coupling material and encapsulating material with the sealed solar cell sandwiched in between the coupling material and the encapsulating material.

In still a further embodiment, the present invention provides a method for manufacturing a solar panel, e.g., module. The method includes providing a first sealed solar cell. As used herein, the term “first” is not intended to be limiting and should be interpreted by its ordinary meaning. The method includes aligning the first sealed solar cell to at least a pair of first electrical contact members coupled to respective first and second bus bar members provided on a base substrate member. The method includes electrically coupling the first sealed solar cell to the pair of first and second bus bar members. The method also includes providing a second sealed solar cell. As used herein, the term “second” is not intended to be limiting and should be interpreted by its ordinary meaning. In a specific embodiment, the method includes aligning the second sealed solar cell to at least a pair of second electrical contact members coupled to respective first and second bus bar members provided on the base substrate member. The method also includes electrically coupling the second sealed solar cell to the pair of the first and second bus bar members according to a specific embodiment. Depending upon the embodiment, the contact members can include a pair of solder bumps, one or more sockets, one or more pins, one or more leads, or any other suitable conduction members, and the like. In alternative embodiments, the first and/or second sealed solar cells can be replaced. That is, the method includes removing either or both the first sealed solar cell or the second sealed solar cell from the substrate member; and replacing either or both the first sealed solar cell or the second sealed solar cell with a third sealed solar cell or the third sealed solar cell and a fourth sealed solar cell. Of course, there can be other variations, modifications, and alternatives.

In yet an alternative embodiment, the present invention provides a solar module, e.g., stand alone module, which may be coupled to one or more other modules. In a specific embodiment, the module includes a sealed solar cell, which has a transparent polymeric member, one or more photovoltaic regions, and a backside member. In a specific embodiment, the transparent polymeric member has a surface region, which can be substantially flat and uniform. In a preferred embodiment, the one or more photovoltaic regions is characterized by a first seal between the transparent polymeric member and a backside member. In a specific embodiment, the solar module includes an encapsulating material overlying the surface region and the backside member to form a second seal encapsulating the solar cell including the one or more of photovoltaic regions and cause formation of a laminated structure including the encapsulating material with the sealed solar cell sandwiched within the encapsulating material.

In an alternative specific embodiment, the present invention provides a method for manufacturing a solar panel, e.g., solar module. In a specific embodiment, the method includes providing a sealed solar cell, which has a transparent polymeric member. In a specific embodiment, the transparent polymeric member has one or more photovoltaic regions coupled to the transparent polymeric member. In a specific embodiment, the one or more photovoltaic regions occupies at least about 10% of an aperture surface region of the transparent polymeric member and up to about 100% of the aperture surface region of the transparent polymeric member. The transparent polymeric member has a surface region, which is substantially flat and uniform. The one or more photovoltaic regions is first sealed between the transparent polymeric member and a backside member to form a solar cell. In a specific embodiment, the method includes providing a double sided tape coupling material overlying the surface region of the transparent polymeric member. As merely an example, the double-coated adhesive tape with superior transparency includes HJ-3160W, HJ-9150W Nitto Denko HJ-3160W and HJ-9150W, which are double-coated adhesive tapes that offer superior transparency. In a preferred embodiment, the tapes offer superior transparency, weather resistance and heat resistance, and can be used for bonding transparent materials. Alternatively, the tape product can include 3M™ Optically Clear Adhesive 8141 (or 8141 and the like), which is a 1.0 mil, highly specialized optically clear free-film adhesive offering superior clarity and adhesion capabilities for use in touch screen displays and other applications requiring an optically clear bond manufactured by 3M Company, 3-M Center, St Paul, Minn. 55144. In a specific embodiment, one side of the double sided tape is first bonded to either the transparent polymeric member or the glass surface region and then the other side of the double sided tape is aligned to and bonded to the non-bonded polymeric member or glass surface to form a sandwiched structure. Of course, there can be other variations, modifications, and alternatives. Additionally, the method includes aligning the surface region of the transparent polymeric member of the solar cell to an optically transparent glass member to form an interface region including the double sided tape coupling material between the surface region and a glass surface region of the transparent glass member. The optically transparent member has a predetermined thickness and surface region, which provides a mechanical structure to support the solar cell thereon. The method includes applying force to at least either or both the transparent glass member and the transparent polymeric member to increase a pressure at the interface region and cause the interface region to change from a first state to a second state. In a specific embodiment, the method includes processing at least the interface region to form a laminated sandwiched structure including the transparent glass member and the transparent polymeric member and cause interface region to change from the second state to a third state while causing the interface to be substantially free from one or more substantial voids in the third state. In a preferred embodiment, the double sided tape is used as an optical coupling material between the transparent glass member and the transparent polymeric member to couple the solar cell to the transparent glass member, which will be used for the solar panel.

In a specific embodiment, the present invention provides a solar panel. The panel includes a sealed solar cell, which has a transparent polymeric member. The transparent polymeric member has one or more photovoltaic regions coupled to the transparent polymeric member. In a specific embodiment, the one or more photovoltaic regions occupies at least about 10% of an aperture surface region of the transparent polymeric member and up to about 100% of the aperture surface region of the transparent polymeric member. In a specific embodiment, the transparent polymeric member has a surface region, which is substantially flat and uniform. In a specific embodiment, the one or more photovoltaic regions is first sealed between the transparent polymeric member and a backside member. In a preferred embodiment, the panel has a double sided tape coupling material overlying the surface region of the transparent polymeric member. In a specific embodiment, the panel also has an optically transparent glass member overlying the double sided tape coupling material. In a preferred embodiment, the panel has an interface region including the double sided tape coupling material between the surface region and a glass surface region of the transparent glass member.

Still further, the present invention provides a solar panel. The panel includes a target board, e.g., printed circuit board, molded member, composite, multilayered structure. In a specific embodiment, the target board includes a surface region and at least a first bus bar and a second bus bar. Depending upon the embodiments, the bus bars can be embedded within the target board and/or be exposed at one or more spatial locations. The surface region (which may be patterned or non-patterned) includes at least a first pair of contact members and a second pair of contact members, e.g., sockets, recessed contact regions, solder bumps, pin holes, contact pads, recessed alignment and contact regions. In a specific embodiment, the panel has a first sealed solar cell coupled to at least the first bus bar and the second bus bar via the first pair of contact members. In a specific embodiment, the sealed solar cell can be similar or the same in design and those described herein. In a specific embodiment, the panel also has a second sealed solar cell coupled to at least the first bus bar and the second bus bar via the second pair of contact members. Depending upon the embodiment, either one or both of these cells can also be removed and replaced.

According to a specific embodiment, the solar cell assembly includes an adhesion promoter and/or enhancer provided on an upper surface of the sealed solar cells, which couples to a transparent member. As an example, the adhesion promoter can be any suitable substance and/or substances known by one of ordinary skill in the art. The adhesion promoter can be provided on the surface that couples to a transparent optical coupling material, which also couples to the transparent member. In a preferred embodiment, the adhesion promoter is optically transparent and can act as a glue and/or barrier layer between the sealed solar cells and the optical coupling material. Of course, there can be other variations modifications, and alternatives.

In another specific embodiment, the solar cell assembly includes surface texturing of the upper surface of the transparent member, which couples to the transparent glass plate. In one or more embodiments, the surface texture can also be used with the adhesion promoter that has been previously described. The surface can be textured in a suitable manner that enhances adhesion between the transparent member and optical coupling material according to a specific embodiment. Depending upon the embodiment, the texture can be a pattern or patterns or other surface characteristics such as changes in spatial features, e.g., roughness, designs. In a preferred embodiment, the textured and/or patterned surface is generally optically transparent and can cause enhancement of the attachment between the transparent polymer member and the optical coupling material. Of course, there can be other variations, modifications, and alternatives.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar panel, which is less costly and easy to handle, using an improved solar cell. Such solar cell uses a plurality of photovoltaic regions, which are sealed within one or more substrate structures according to a preferred embodiment. In a preferred embodiment, the invention provides a method and completed solar panel structure using a plurality of solar cells including a plurality of photovoltaic strips. Also in a preferred embodiment, one or more of the solar cells have less silicon per area (e.g., 80% or less, 50% or less) than conventional solar cells. In preferred embodiments, the present method and cell structures are also light weight and not detrimental to building structures and the like. That is, the weight is about the same or slightly more than conventional solar cells at a module level according to a specific embodiment. In a preferred embodiment, the present solar cell using the plurality of photovoltaic strips, which is more robust, can be used as a “drop in” replacement of conventional solar cell structures. As a drop in replacement, the present solar cell can be used with conventional solar cell technologies for efficient implementation according to a preferred embodiment. In preferred embodiments, the present method and system provides for less use of silicon material than conventional solar cells. In a preferred embodiment, the present method is less prone to solar cell breakage, which will lead to higher yields, etc. In other embodiments, the present method and structures provides for a multi-sealed (e.g., two or more) photovoltaic region to prevent degradation from moisture, and other undesirable influences. In one or more embodiments, the present invention provides a method capable of being provided at a low temperature to maintain the polymeric material. Such temperature can be less than about 175 Degrees Celsius and is preferably less than about 150 Degrees Celsius to prevent any damage to the polymeric material and other structures, which also include combination of structures. Of course, there can be other variations, modifications, and alternatives. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified flow diagram illustrating a method for assembling a solar panel according to an embodiment of the present invention;

FIGS. 2 and 2A are more detailed flow diagrams illustrating a method for assembling a solar panel according to an alternative embodiment of the present invention;

FIG. 3 is a simplified diagram of a solar cell according to an embodiment of the present invention;

FIG. 4 is a simplified cross-sectional view diagram of a solar cell according to an embodiment of the present invention;

FIG. 5 is a simplified cross-section of a solar cell according to an embodiment of the present invention;

FIG. 6 is a simplified cross section of a solar cell according to an alternative embodiment of the present invention;

FIG. 7 is a simplified side view diagram of an optically transparent member for a solar panel according to an embodiment of the present invention;

FIG. 8 is a top-view and side view diagram of a solar panel according to an embodiment of the present invention;

FIGS. 9 through 16 are simplified diagrams illustrating a method for assembling a solar panel according to embodiments of the present invention;

FIGS. 17 through 21 are simplified diagrams illustrating an alternative method for assembling a solar panel according to embodiments of the present invention; and

FIGS. 22 through 24 are simplified diagrams of assembling one or more solar cells onto a target board according to embodiments of the present invention.

### DETAILED DESCRIPTION OF THE INVENTION

According to the present invention, techniques related to solar energy are provided. More particularly, the present invention provides a method and resulting solar panel apparatus fabricated from a solar cell including a plurality of photovoltaic regions provided within one or more substrate members. Merely by way of example, the invention has been applied to a solar cell including the plurality of photovoltaic regions, but it would be recognized that the invention has a much broader range of applicability.

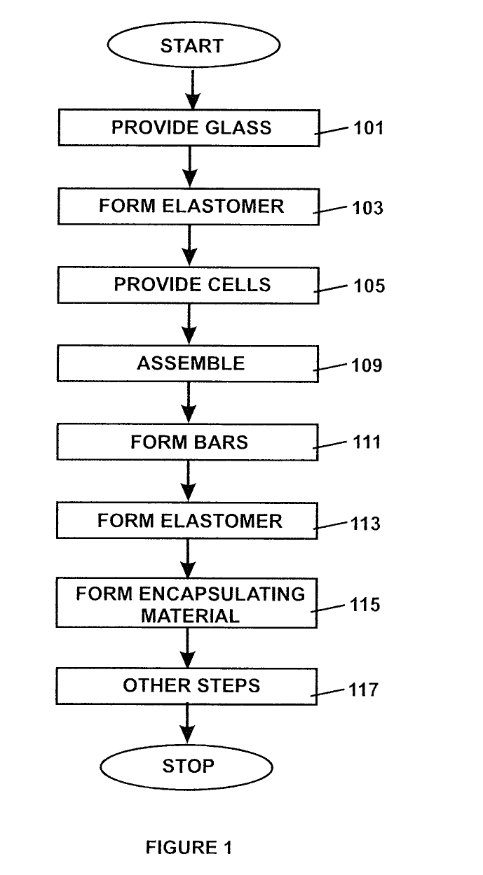

A method 100 for fabricating a solar cell panel structure according to an embodiment of the present invention may be outlined as follows and has been illustrated in FIG. 1:
1. Provide a cover glass (step 101);
2. Form a first layer (e.g., liquid, fluid, tape, sheet, multilayered structure) of elastomer material (e.g., EVA) (step 103) overlying a top surface of the cover glass;
3. Provide a plurality of solar cells (step 105) including photovoltaic regions;
4. Assemble (step 109) the plurality of solar cells, which are coupled to each other, overlying the first layer of elastomer material;
5. Form one or more connection bars (step 111) overlying the plurality of solar cells;
6. Form a second layer of elastomer material (step 113) overlying the plurality of solar cells;
7. Form an encapsulating layer (step 115) (e.g., barrier layer, back cover sheet (e.g., Dupont Tedlar® polyvinyl fluoride (PVF) products manufactured by E.I. du Pont de Nemours and Company, which are a part of the DuPont fluoropolymer family, Aclar® film is a polychlorotrifluoroethylene (PCTFE) material manufactured by Honeywell International Inc) overlying the elastomer material; and
8. Perform other steps (step 117), as desired.

The above sequence of steps provides a method according to an embodiment of the present invention. As shown, the method uses a combination of steps including a way of forming a solar panel, which has a plurality of solar cells using regions of photovoltaic material. Other alternatives can also be provided where steps are added, one or more steps are removed, or one or more steps are provided in a different sequence without departing from the scope of the claims herein. Further details of the present method and resulting structures can be found throughout the present specification and more particularly below.

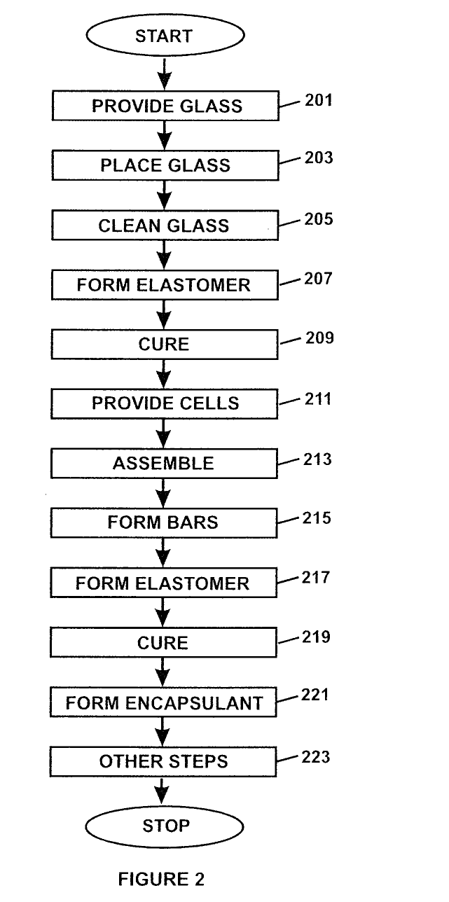

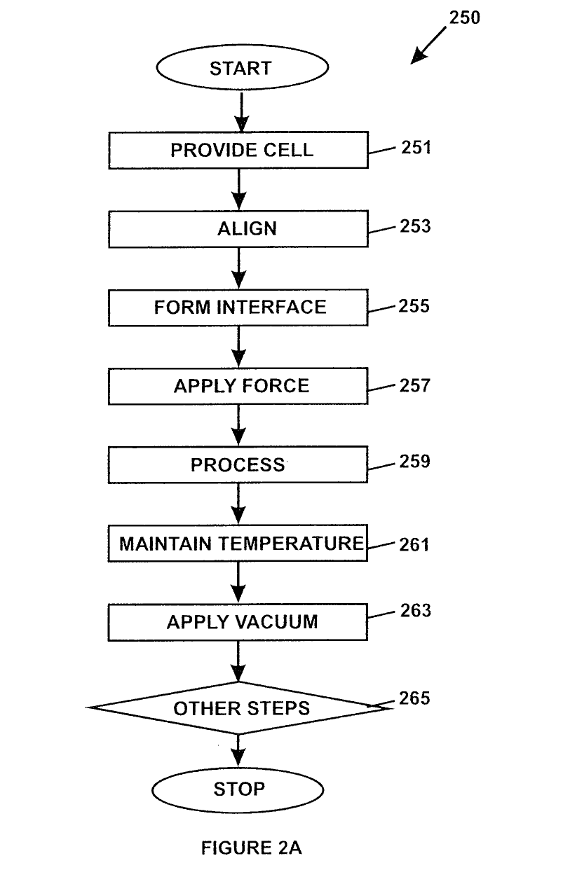

A method 200 for fabricating a solar cell panel structure according to an alternative embodiment of the present invention may be outlined as follows and has been illustrated in FIGS. 2 and 2A:
1. Provide a cover glass (step 201);
2. Place cover glass on workstation (step 203);
3. Clean cover glass (step 205);
4. Form via deposition a first layer of elastomer material (e.g., EVA) (step 207) overlying a top surface of the cover glass;
5. Cure first layer of elastomer material (step 209) (or cause the first layer of elastomer material to be substantially uniform in shape, density, and texture);
6. Provide a plurality of solar cells (step 211) including photovoltaic regions;
7. Assemble the plurality of solar cells (step 213), which are coupled to each other, overlying the first layer of elastomeric material;
8. Form one or more connection bars (step 215) overlying the plurality of solar cells;
9. Form via deposition a second layer (step 217) of elastomer material overlying the plurality of solar cells;
10. Cure second layer of elastomer material (step 219);
11. Form an encapsulating layer (step 221) (e.g., barrier layer, back cover sheet (e.g., Dupont Tedlar® polyvinyl fluoride (PVF) products manufactured by E.I. du Pont de Nemours and Company, which are a part of the DuPont fluoropolymer family, Aclar® film is a polychlorotrifluoroethylene (PCTFE) material manufactured by Honeywell International Inc) overlying the elastomer material; and
12. Perform other steps (step 223), as desired.

The above sequence of steps provides a method according to an embodiment of the present invention. As shown, the method uses a combination of steps including a way of forming a solar panel, which has a plurality of solar cells using regions of photovoltaic material. Other alternatives can also be provided where steps are added, one or more steps are removed, or one or more steps are provided in a different sequence without departing from the scope of the claims herein. Further details of the present method and resulting structures can be found throughout the present specification and more particularly below.

In an alternative specific embodiment, the present invention provides a method (step 250) for manufacturing a solar panel using a low temperature thermal treatment process, which has a temperature characteristic of less than 170 Degrees Celsius (See FIG. 2A).

1. Provide a solar cell (step 251), which including a plurality of photovoltaic regions coupled to the transparent polymeric member;

2. Align (step 253) a surface region of the transparent polymeric member of the solar cell to an optically transparent glass member;

3. Form an interface region (step 255) between the surface region and a glass surface region of the transparent glass member, which has a predetermined thickness and surface region according to a specific embodiment;

4. Apply force (e.g., mechanical) (step 257) on either or both the transparent glass member and the transparent polymeric member to cause an increase in pressure at the interface region to change from a first state to a second state;

5. Process (step 259) at least the interface region using a thermal process to form a laminated sandwiched structure including the transparent glass member and the transparent polymeric member and cause the interface region to change from the second state to a third state;

6. Maintain (step 261) the thermal process at a temperature below about 170 Degrees Celsius to cause formation of the laminated structure and cause the interface region to be substantially free from one or more substantial voids in the third state;

7. Apply a vacuum (step 263) on at least the interface region to cause the interface region to be substantially free from voids concurrent with the thermal treatment (concurrent with the thermal process); and

8. Perform other steps (step 265), as desired.

The above sequence of steps provides a method according to an embodiment of the present invention. As shown, the method uses a combination of steps including a way of forming a solar panel, which has a plurality of solar cells using regions of photovoltaic material. Other alternatives can also be provided where steps are added, one or more steps are removed, or one or more steps are provided in a different sequence without departing from the scope of the claims herein. Further details of the present method and resulting structures can be found throughout the present specification and more particularly below.

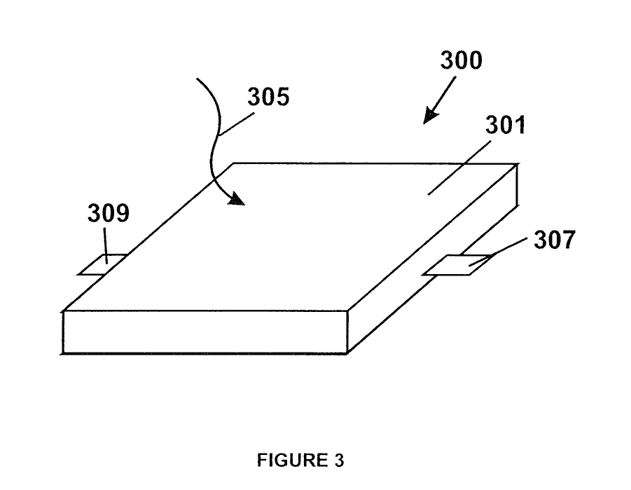

FIG. 3 is a simplified diagram of a solar cell 300 according to an embodiment of the present invention. This diagram is merely an example, which should not unduly limit the scope of the claims herein. One of ordinary skill in the art would recognize many variations, alternatives, and modifications. As shown, the solar cell 300 includes an aperture region 301, which receives electromagnetic radiation in the form of sunlight 305. The cell is often a square or trapezoidal shape, although it may also be other shapes, such as annular, circular, or any combination of these, and the like. As also shown, the cell includes a first electrical connection 309 region and a second electrical connection region 307. Each of these electrical connection regions couple to other cell structures or a bus structure that couples the cells together in a panel, which will be described throughout the present specification and more particularly below.

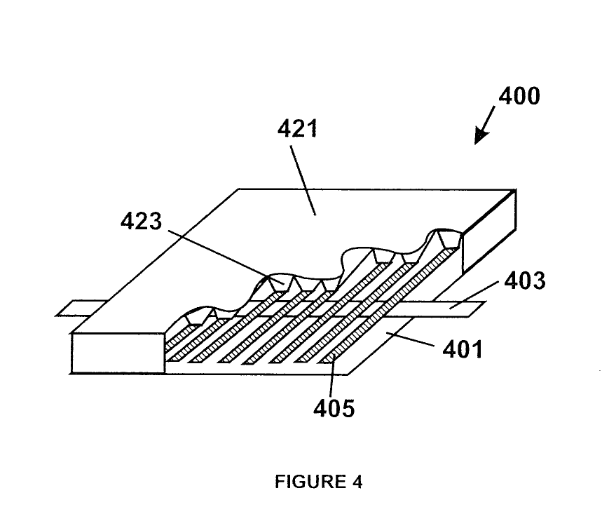

FIG. 4 is a simplified cross-sectional view diagram of a solar cell 400 according to an embodiment of the present invention. This diagram is merely an example, which should not unduly limit the scope of the claims herein. One of ordinary skill in the art would recognize many variations, alternatives, and modifications. As shown, the device has a back cover member 401, which includes a surface area and a back area. The back cover member also has a plurality of sites, which are spatially disposed, for electrical members 403, such as bus bars, and a plurality of photovoltaic regions.

In a preferred embodiment, the device has a plurality of photovoltaic strips 405, each of which is disposed overlying the surface area of the back cover member. In a preferred embodiment, the plurality of photovoltaic strips correspond to a cumulative area occupying a total photovoltaic spatial region, which is active and converts sunlight into electrical energy. As another example, each of the photovoltaic strips is made of a material selected from mono-crystalline silicon, poly-crystalline silicon, amorphous silicon copper indium diselenide (CIS), cadmium telluride CdTe, or nanostructured materials. Each of the strips and/or regions include active junction regions with for example p-type and n-type impurities to induce currents upon application of electromagnetic radiation according to a specific embodiment. Of course, there can be other variations, modifications, and alternatives.

An encapsulating material (not shown) is overlying a portion of the back cover member. That is, an encapsulating material forms overlying the plurality of strips, and exposed regions of the back cover, and electrical members. In a preferred embodiment, the encapsulating material can be a single layer, multiple layers, or portions of layers, depending upon the application.

In a specific embodiment, a front cover member 421 is coupled to the encapsulating material. That is, the front cover member is formed overlying the encapsulant to form a multilayered structure including at least the back cover, bus bars, plurality of photovoltaic strips, encapsulant, and front cover. In a preferred embodiment, the front cover includes one or more concentrating elements 423, which concentrate (e.g., intensify per unit area) sunlight onto the plurality of photovoltaic strips. That is, each of the concentrating elements can be associated respectively with each of or at least one of the photovoltaic strips.

Upon assembly of the back cover, bus bars, photovoltaic strips, encapsulant, and front cover, an interface region is provided along at least a peripheral region of the back cover member and the front cover member. The interface region may also be provided surrounding each of the strips or certain groups of the strips depending upon the embodiment. The device has a sealed region and is formed on at least the interface region to form an individual solar cell from the back cover member and the front cover member. The sealed region maintains the active regions, including photovoltaic strips, in a controlled environment free from external effects, such as weather, mechanical handling, environmental conditions, and other influences that may degrade the quality of the solar cell. Additionally, the sealed region and/or sealed member (e.g., two substrates) protect certain optical characteristics associated with the solar cell and also protects and maintains any of the electrical conductive members, such as bus bars, interconnects, and the like. Of course, there can be other benefits achieved using the sealed member structure according to other embodiments.

In a preferred embodiment, the total photovoltaic spatial region occupies a smaller spatial region than the surface area of the back cover. That is, the total photovoltaic spatial region uses less silicon than conventional solar cells for a given solar cell size. In a preferred embodiment, the total photovoltaic spatial region occupies about 80% and less of the surface area of the back cover for the individual solar cell. Depending upon the embodiment, the photovoltaic spatial region may also occupy about 70% and less or 60% and less or preferably 50% and less of the surface area of the back cover or given area of a solar cell. Of course, there can be other percentages that have not been expressly recited according to other embodiments. Here, the terms “back cover member” and “front cover member” are provided for illustrative purposes, and not intended to limit the scope of the claims to a particular configuration relative to a spatial orientation according to a specific embodiment. Further details of the solar cell can be found throughout the present specification and more particularly below.

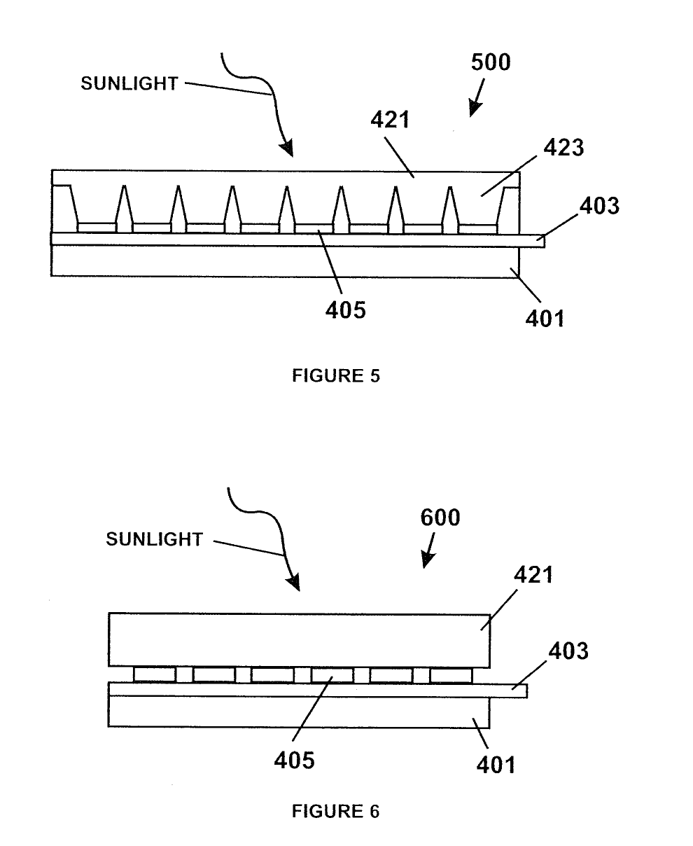

FIG. 5 is a simplified cross-section of a solar cell 500 according to an embodiment of the present invention. This diagram is merely an example, which should not unduly limit the scope of the claims herein. One of ordinary skill in the art would recognize many variations, alternatives, and modifications. Like reference numerals are used in the present diagram as other described herein, but are not intended to be limiting the scope of the claims herein. As shown, the solar cell includes a back cover 401, which has a plurality of electrical conductors 403. The back cover also includes a plurality of photovoltaic regions 405. Each of the photovoltaic regions couples to concentrator 423, which is provided on top cover member 421. Of course, there can be other variations, modifications, and alternatives.

FIG. 6 is a simplified cross section of a solar cell 600 according to an alternative embodiment of the present invention. This diagram is merely an example, which should not unduly limit the scope of the claims herein. One of ordinary skill in the art would recognize many variations, alternatives, and modifications. Like reference numerals are used in the present diagram as other described herein, but are not intended to be limiting the scope of the claims herein. As shown, the solar cell includes a back cover 401, which has a plurality of electrical conductors 403. The back cover also includes a plurality of photovoltaic regions 405. Each of the photovoltaic regions couples to concentrator 423, which is provided on top cover member 421. Of course, there can be other variations, modifications, and alternatives. Specific details on using these solar cells for manufacturing solar panels can be found throughout the present specification and more particularly below.

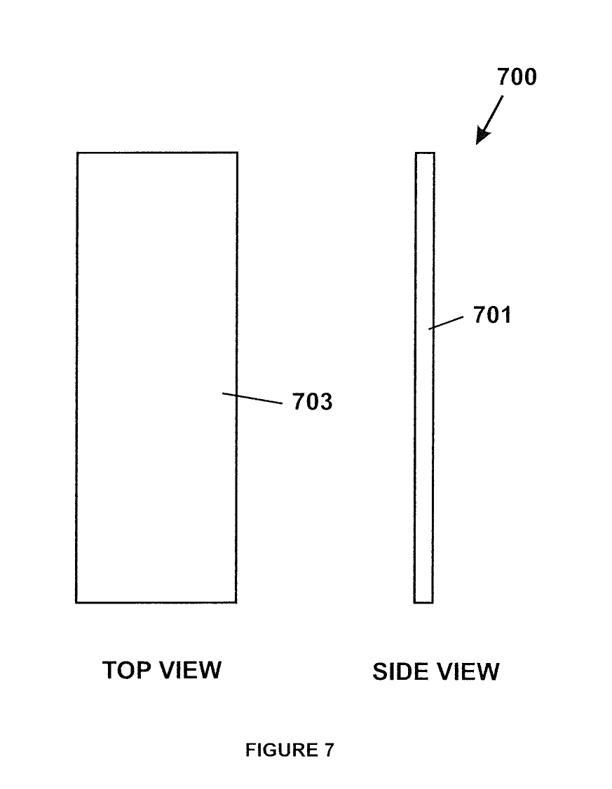

FIG. 7 is a simplified side view diagram of an optically transparent member 700 for a solar panel according to an embodiment of the present invention. This diagram is merely an example, which should not unduly limit the scope of the claims herein. One of ordinary skill in the art would recognize many variations, alternatives, and modifications. As shown, the optically transparent member 700 is illustrated in a side view diagram 701 and a top-view or back-view diagram 703. The side view diagram illustrates a member having a certain thickness, which can range from about ⅛″ or less to about ¼″ or more in a specific embodiment. Alternatively, the thickness can be about ⅜″ and the like. Of course, the thickness will depending upon the specific application. Additionally, the member is often made of an optically transparent material, which may be composed of a single material, multiple materials, multiple layers, or any combination of these, and the like. As merely an example, the optically transparent material is called Krystal Klear™ optical glass manufactured by AFG Industries, Inc., but can be others. Of course, there can be other variations, modifications, and alternatives.

As also shown, the optically transparent member has a length, a width, and the thickness as noted. The member often has a length ranging from about 12″ to greater than 130″ according to a specific embodiment. The width often ranges from about 12″ to greater than 96″ according to a specific embodiment. The member serves as an “aperture” for sunlight to be directed onto one of a plurality of solar cells according to an embodiment of the present invention. As will be shown, the member serves as a starting point for the manufacture of the present solar panels according to an embodiment of the present invention. Of course, there can be other variations, modifications, and alternatives.

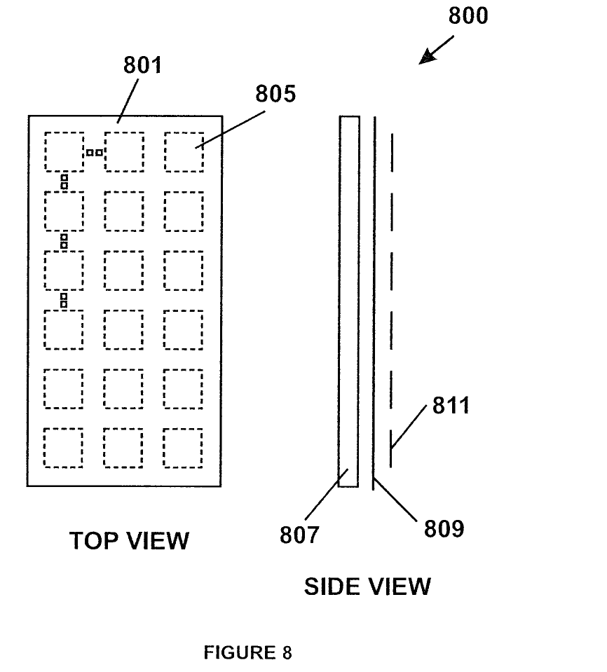

FIG. 8 is a top-view and side view diagram of a solar panel 800 according to an embodiment of the present invention. This diagram is merely an example, which should not unduly limit the scope of the claims herein. One of ordinary skill in the art would recognize many variations, alternatives, and modifications. As shown, the side-view diagram includes the optical transparent member 807, which couples to polymeric coupling material 809, which couples to a plurality of solar cells 811, among other elements. The top-view diagram illustrates the plurality of solar cells 805 and overlying optical transparent member 801. Of course, one of ordinary skill in the art would recognize many other variations, modifications, and alternatives. Further details of the present solar panel and its manufacture can be found throughout the present specification and more particularly below.

In a specific embodiment, the present method and structure includes a polymeric coupling material 809, which can be a double sided tape or like structure. The tape is characterized by a thickness, length, and width according to a specific embodiment. The tape is mechanically solid and includes adhesives on each side according to a specific embodiment. The tape is characterized by a transmittance of about 98% or 99% and greater for wavelengths ranging from about 380 to about 780 nanometers according to a specific embodiment. In a specific embodiment, the tape can be used to mechanically couple the solar cell to the optically transparent member. Depending upon the embodiment, the tape can be used as a coupling material for smooth, textured, or rough surfaces characterizing the optically transparent member. In preferred embodiments, the optically transparent member is smooth to reduce internal reflection. In a specific embodiment, the present method and structure provides the double sided tape coupling material overlying the surface region of the transparent polymeric member. In a specific embodiment, the tape has a haze level of about 1% and less. Additionally, the tape can withstand high temperature, humidity, and UV resistance according to a specific embodiment. The tape is also substantially free from particulate contamination according to a specific embodiment. As merely an example, the double-coated adhesive tape with superior transparency includes HJ-3160W, HJ-9150W Nitto Denko HJ-3160W and HJ-9150W, which are double-coated adhesive tapes that offer superior transparency. In a preferred embodiment, the tapes offer superior transparency, weather resistance and heat resistance, and can be used for bonding transparent materials. Alternatively, the tape product can include 3M™ Optically Clear Adhesive 8141 (or 8141 and the like), which is a 1.0 mil, highly specialized optically clear free-film adhesive offering superior clarity and adhesion capabilities for use in touch screen displays and other applications requiring an optically clear bond manufactured by 3M Company, 3-M Center, St Paul, Minn. 55144. In a preferred embodiment, the tape also provides a final interface that is substantially free from bubbles (e.g., voids), dirt, gels, and other imperfections that may lead to optical distortion. Of course, there can be other variations, modifications, and alternatives.

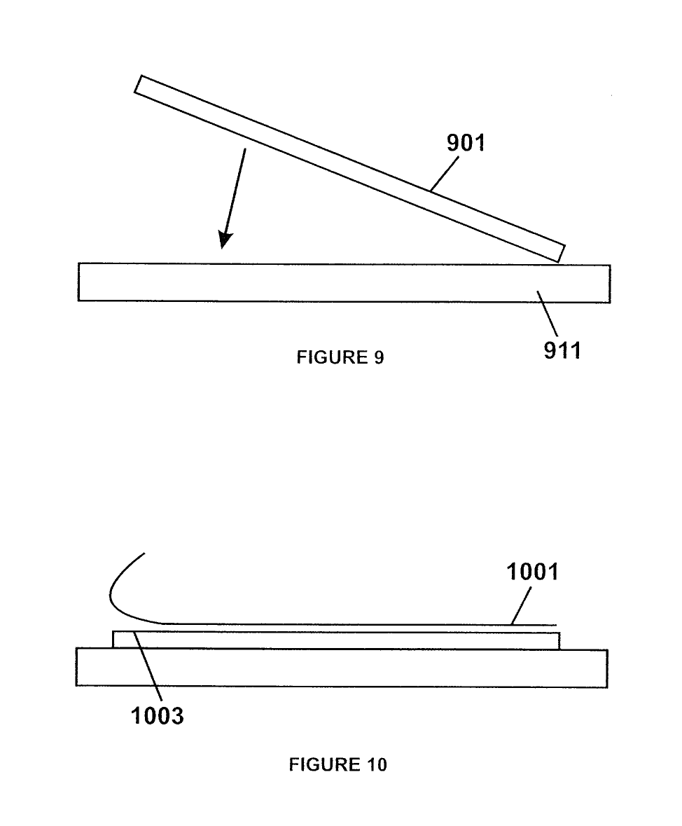

FIGS. 9 through 16 are simplified diagrams illustrating a method for assembling a solar panel according to embodiments of the present invention. These diagrams are merely examples, which should not unduly limit the scope of the claims herein. One of ordinary skill in the art would recognize many variations, alternatives, and modifications. As shown, the method begins by providing a cover glass, which is an optically transparent member. The optically transparent member has suitable characteristics, which will be described in more detail below.

That is, the member has a certain thickness, which can range from about ⅛″ or less to about ¼″ (or ⅜″) or more according to a specific embodiment. Of course, the thickness will depending upon the specific application. Additionally, the member is often made of an optically transparent material, which may be composed of a single material, multiple materials, multiple layers, or any combination of these, and the like. As merely an example, the optically transparent material is called Krystal Klear™ optical glass manufactured by AFG Industries, Inc., but can be others. Of course, there can be other variations, modifications, and alternatives.

As also shown, the optically transparent member has a length, a width, and the thickness as noted. The member often has a length ranging from about 12″ to greater than 130″ according to a specific embodiment. The width often ranges from about 12″ to greater than 96″ according to a specific embodiment. The member serves as an “aperture” for sunlight to be directed onto one of a plurality of solar cells according to an embodiment of the present invention. As will be shown, the member serves as a starting point for the manufacture of the present solar panels according to an embodiment of the present invention. Of course, there can be other variations, modifications, and alternatives.

As shown, the member is provided on workstation 911. The work station can be a suitable place to process the member. The work station can be a table or in a tool, such as cluster tool, or the like. The table or tool can be in a clean room or other suitable environment. As merely an example, the environment is preferably a Class 10000 (ISO Class 7) clean room or better, but can be others. Of course, one of ordinary skill in the art would recognize many variations, alternatives, and modifications.

Depending upon the embodiment, the cover glass is processed. That is, the cover glass may be subjected to a cleaning process or other suitable process in preparation for fabricating other layers thereon. In a specific embodiment, the method cleans the cover glass using an ultrasonic bath process. Alternatively, other processes such as glass wiping with a lint free cloth may be used. The surfaces of the cover glass are free from particles and other contaminants, such as oils, etc. according to a specific embodiment. Of course, one of ordinary skill in the art would recognize many variations, alternatives, and modifications.

Referring now to FIG. 10, the method forms an encapsulating material (first layer) overlying a surface of the cover glass. This diagram is merely an example, which should not unduly limit the scope of the claims herein. One of ordinary skill in the art would recognize many variations, alternatives, and modifications. As used herein, the terms “first” and “second” are not intended to be limiting in any manner and are merely be used for reference purposes. The encapsulating material is preferably provided via deposition of a first layer of encapsulating material (e.g., EVA) overlying a top surface of the cover glass. In a specific embodiment, the encapsulating material is suitably a polymer material that is UV stable. As merely an example, the encapsulating material is a thermoplastic polyurethane material such as those called ETIMEX® film from Vistasolar containing Desmopan® film manufactured by Bayer Material Science AG of Germany, but can be others. An alternative example of such an encapsulating material is Elvax® EVA manufactured by DuPont of Delaware USA, but can be others. Alternatively, the material can be polyvinyl butyral (commonly called “PVB”), which is a resin usually used for applications that desire binding, optical clarity, adhesion, toughness and flexibility, and possibly other characteristics. Depending upon the embodiment, PVB is often prepared from polyvinyl alcohol by reaction with butanal. The encapsulating material is preferably cured (e.g., fused or cross-linked) according to a specific embodiment. In a preferred embodiment, the encapsulating material has a desirable optical property. The encapsulating material has a protecting capability to maintain moisture and/or other contaminants away from certain devices elements according to alternative embodiments. The encapsulating material also can be a filler or act as a fill material according to a specific embodiment. In a specific embodiment, the encapsulating material has an index of refraction ranging from about 1.45 and greater. Of course, there can be other variations, modifications, and alternatives. Depending upon the embodiment, the encapsulating material also provides thermal compatibility between different materials that are provided on either side of the encapsulating material.

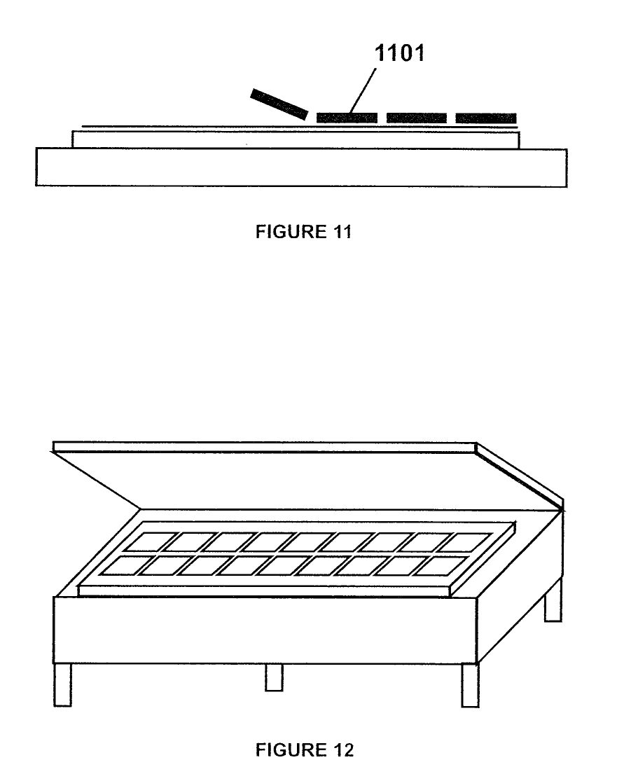

Referring now to FIG. 11, the method provides a plurality of solar cells including photovoltaic regions 1101. This diagram is merely an example, which should not unduly limit the scope of the claims herein. One of ordinary skill in the art would recognize many variations, alternatives, and modifications. Each of the solar cells include a plurality of photovoltaic regions and/or strips according to a specific embodiment. The method assembles the plurality of solar cells, which are coupled to each other, overlying the layer of encapsulating material to form a multilayered structure. As shown, the optically transparent member serves as an aperture, which couples to aperture regions of the solar cells. In a preferred embodiment, each of the solar cells is aligned to each other via a mechanical self-alignment mechanism, electrically coupling device, or other device that causes a physical location of each of the cells to be substantially fixed in spatial position along a region of the transparent member. The mechanical alignment mechanism may be a portion of the electrical connections on each of the solar cells or other portions of the solar cell depending upon the specific embodiment. In a specific embodiment, the self-alignment mechanism also keys the electrical interconnect such that the polarity between cells is always correct to prevent assembly problems. The self-alignment mechanism is designed into the cells as a “tongue and groove” or notches and nibs, or other configurations. The cells are placed next to each other such that the alignment features interlock with each other. Of course, one of ordinary skill in the art would recognize many variations, modifications, and alternatives.

In a specific embodiment, the present method and structure includes a polymeric coupling material, which can be a double sided tape or like structure. The tape is characterized by a thickness, length, and width according to a specific embodiment. The tape is mechanically solid and includes adhesives on each side according to a specific embodiment. The tape is characterized by a transmittance of about 98% or 99% and greater for wavelengths ranging from about 380 to about 780 nanometers according to a specific embodiment. In a specific embodiment, the tape can be used to mechanically couple the solar cell to the optically transparent member. Depending upon the embodiment, the tape can be used as a coupling material for smooth, textured, or rough surfaces characterizing the optically transparent member. In preferred embodiments, the optically transparent member is smooth to reduce internal reflection. In a specific embodiment, the present method and structure provides the double sided tape coupling material overlying the surface region of the transparent polymeric member. In a specific embodiment, the tape has a haze level of about 1% and less. Additionally, the tape can withstand high temperature, humidity, and UV resistance according to a specific embodiment. The tape is also substantially free from particulate contamination according to a specific embodiment. As merely an example, the double-coated adhesive tape with superior transparency includes HJ-3160W, HJ-9150W Nitto Denko HJ-3160W and HJ-9150W, which are double-coated adhesive tapes that offer superior transparency. In a preferred embodiment, the tapes offer superior transparency, weather resistance and heat resistance, and can be used for bonding transparent materials. Alternatively, the tape product can include 3M™ Optically Clear Adhesive 8141 (or 8141 and the like), which is a 1.0 mil, highly specialized optically clear free-film adhesive offering superior clarity and adhesion capabilities for use in touch screen displays and other applications requiring an optically clear bond manufactured by 3M Company, 3-M Center, St Paul, Minn. 55144. In a preferred embodiment, the tape also provides a final interface that is substantially free from bubbles (e.g., voids), dirt, gels, and other imperfections that may lead to optical distortion. Of course, there can be other variations, modifications, and alternatives.

In a specific embodiment, the method includes laminating the multilayered structure using a laminating apparatus, as shown in FIG. 12. This diagram is merely an example, which should not unduly limit the scope of the claims herein. One of ordinary skill in the art would recognize many variations, alternatives, and modifications. That is, the multilayered structure is subjected to suitable conditions and processes for lamination to occur, which essentially bonds the layers together according to a specific embodiment. As merely an example, a EVA laminate material is heated to a temperature of at least 150 Celsius for about 10 to 15 minutes to cure and/or cross-like the polymers in the encapsulant material according to a specific embodiment. As shown, each of the solar cells becomes substantially fixed onto surfaces of the transparent member according to a specific embodiment. Of course, one of ordinary skill in the art would recognize many variations, modifications, and alternatives.

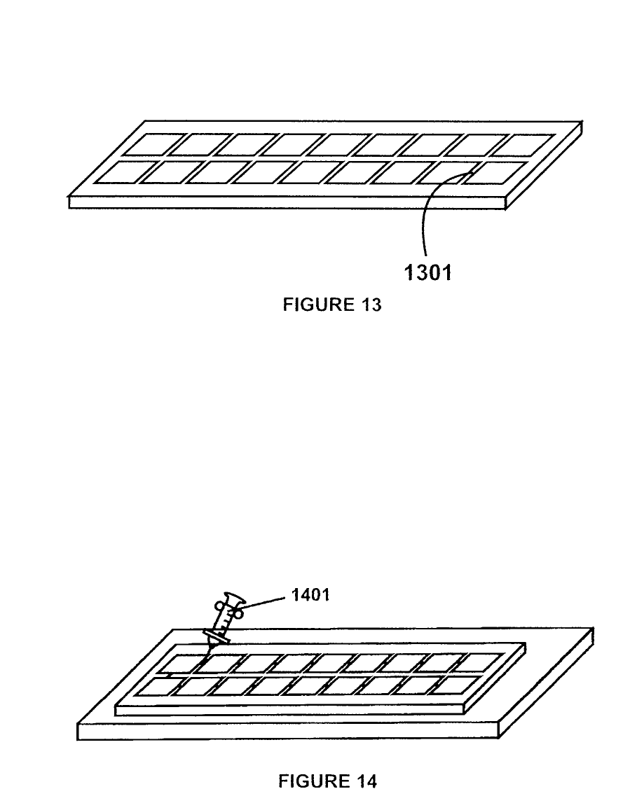

Referring to FIG. 13, the method includes forming electrical connections 1301 between one or more of the solar cells. That is, each of the solar cells may be coupled to each other in series and/or parallel depending upon a specific embodiment. In a preferred embodiment, the method couples the solar cells together in series from a first solar cell, a second solar cell, and an Nth solar cell, which is the last solar cell on the panel assembly. The first electrical connection of one cell is connected to the second electrical connection of next cell in series. In a preferred embodiment the electrical connection is made by attaching a wire or metal strip across the first and second electrical connections of adjacent cells. The wire or metal strip is then soldered at both ends to the cells' electrical connections. Alternatively, other processes such as using electrically conducting epoxies or adhesives to attach the wire or metal strip to the cells' electrical connections could be used. Of course, one of ordinary skill in the art would recognize many variations, modifications, and alternatives.

In a specific embodiment, the method forms via deposition 1401 a second layer of encapsulating material overlying the plurality of solar cells, as illustrated in the simplified diagram of FIG. 14. The encapsulating material is preferably provided via deposition of the encapsulating material overlying the electrical connections and may also be overlying backside regions of the solar cells depending upon the specific embodiment. In a specific embodiment, the encapsulating material is suitably a silicone pottant that has high electrical insulation, low water absorption, and excellent temperature stability. Other types of materials may include Parylene based materials according to a specific embodiment. As merely an example, the encapsulating material is a pottant material such as those called OR-3100 low viscosity pottant kit from Dow Corning, USA, but can be others. The encapsulating material is preferably cured according to a specific embodiment. As shown, the encapsulant material occupies regions in a vicinity of the electrical connections according to a specific embodiment. Alternatively, the method forms an encapsulating layer overlying the second elastomer material according to a specific embodiment. Of course, one of ordinary skill in the art would recognize other variations, modifications, and alternatives.

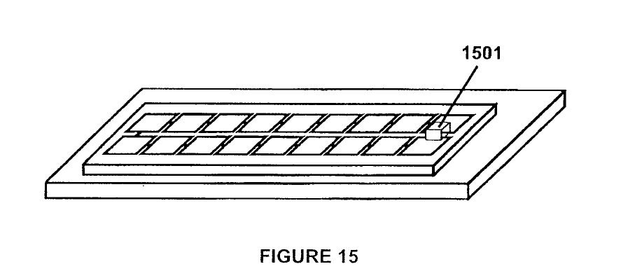

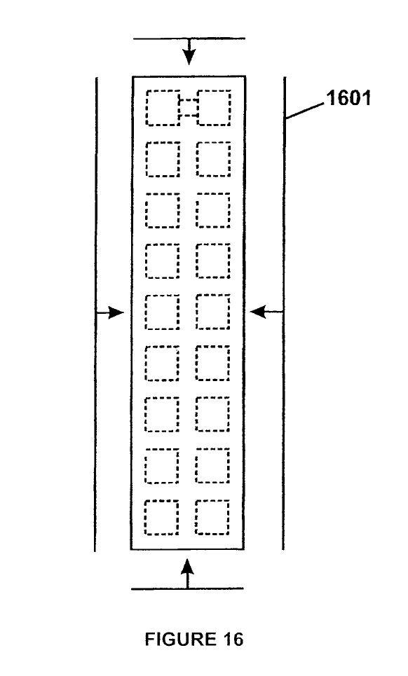

Referring now to FIGS. 15 and 16, the method assemblies one or more junction boxes 1501 onto portions of the electrical interconnects. The method also attaches one or more frame members 1601 onto edges or side portions of the optically transparent member including the plurality of solar cells. In a specific embodiment, the junction box is used to electrically connect the module to other modules or to the electrical load. The junction box contains connection terminals for the external wires and connection terminals for the internal electrical leads to the cells in the module. The junction box may also house the bypass diode used to protect the module when it is shaded. The junction box is placed on the back or side of the module such that connections to the first and last cells in the interconnected series of cells is easily accessible. The junction box is attached and sealed to the module using RTV silicon. Electrical connections are made through soldering, screw terminals, or as defined by the junction box manufacturer. As merely an example, the SOLARLOK™ interconnect system from Tyco Electronics could be used to provide the junction box and interconnects, but can be others. The module frame is attached to the sides of the module to provide for easy mounting, electrical grounding, and mechanical support. In a preferred embodiment, the frames are made from extruded aluminum cut to length. Two lengths would have counter-sunk holes to provide for screw passage. The remaining two lengths would have predrilled or hollow area for the screws to fasten. The extruded aluminum would contain channels designed to capture the laminate. A foam strip is placed around the edges of the module and then the extruded aluminum channel is pressed over the foam. When all four sides are properly located, two screws at each corner are inserted to hold the frame together. In an alternate embodiment, the frame could be provided by a molded polymer with or without a metal support structure, As shown, the present method forms a resulting structure that may exposed certain backside regions of the solar cells, which are characterized by sealed backside regions, according to specific embodiments. Of course, one of ordinary skill in the art would recognize many variations, modifications, and alternatives.

The above sequence of steps provides a method according to an embodiment of the present invention. As shown, the method uses a combination of steps including a way of forming a solar panel, which has a plurality of solar cells using regions of photovoltaic material. Other alternatives can also be provided where steps are added, one or more steps are removed, or one or more steps are provided in a different sequence without departing from the scope of the claims herein.

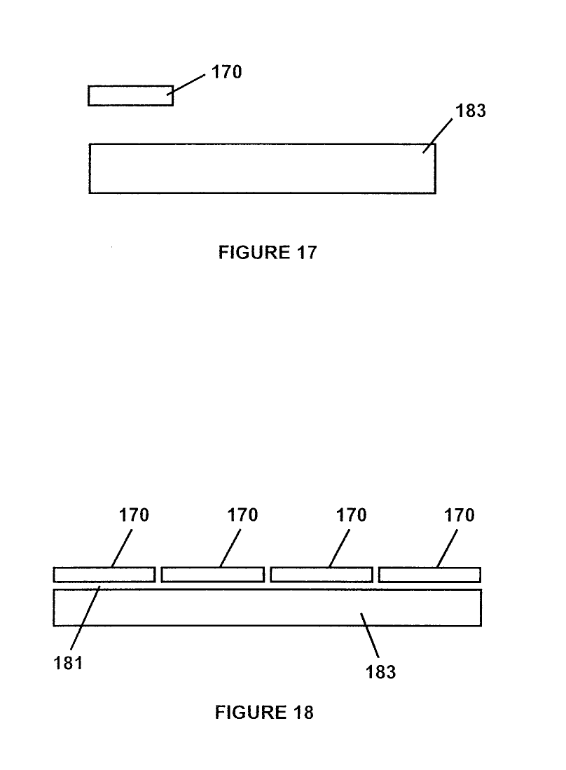

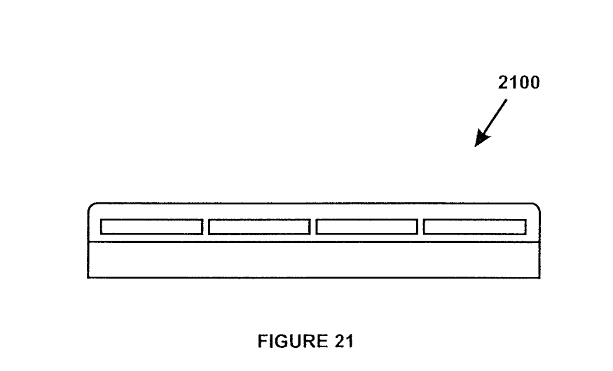

FIGS. 17 through 21 are simplified diagrams illustrating an alternative method for assembling a solar panel according to embodiments of the present invention. These diagrams are merely examples, which should not unduly limit the scope of the claims herein. One of ordinary skill in the art would recognize many variations, alternatives, and modifications. As shown, the method begins by providing a cover glass 183, which is an optically transparent member. The optically transparent member has suitable characteristics, which will be described in more detail below.

That is, the member has a certain thickness, which can range from about ⅛″ or less to about ¼″ (or ⅜″) or more according to a specific embodiment. Of course, the thickness will depending upon the specific application. Additionally, the member is often made of an optically transparent material, which may be composed of a single material, multiple materials, multiple layers, or any combination of these, and the like. As merely an example, the optically transparent material is called Krystal Klear™ optical glass manufactured by AFG Industries, Inc., but can be others.

As also shown, the optically transparent member has a length, a width, and the thickness as noted. The member often has a length ranging from about 12″ to greater than 130″ according to a specific embodiment. The width often ranges from about 12″ to greater than 96″ according to a specific embodiment. The member serves as an “aperture” for sunlight to be directed onto one of a plurality of solar cells according to an embodiment of the present invention. As will be shown, the member serves as a starting point for the manufacture of the present solar panels according to an embodiment of the present invention. Of course, there can be other variations, modifications, and alternatives.

In a specific embodiment, the member can be provided on workstation. The work station can be a suitable place to process the member. The work station can be a table or in a tool, such as cluster tool, or the like. The table or tool can be in a clean room or other suitable environment. As merely an example, the environment is preferably a Class 10000 (ISO Class 7) clean room or better, but can be others. Of course, one of ordinary skill in the art would recognize many variations, alternatives, and modifications.

Depending upon the embodiment, the cover glass is processed. That is, the cover glass may be subjected to a cleaning process or other suitable process in preparation for fabricating other layers thereon. In a specific embodiment, the method cleans the cover glass using an ultrasonic bath process. Alternatively, other processes such as glass wiping with a lint free cloth may be used. The surfaces of the cover glass are free from particles and other contaminants, such as oils, etc. according to a specific embodiment. Of course, one of ordinary skill in the art would recognize many variations, alternatives, and modifications.

Referring again to FIG. 17, the method provides a solar cell device 170. The solar cell device is desirably a packaged device. In a specific embodiment, the solar cell device includes a plurality of photovoltaic regions coupled to a transparent polymeric member. In a specific embodiment, the plurality of photovoltaic regions occupies at least about 10% of an aperture surface region of the transparent polymeric member and up to about 80% of the aperture surface region of the transparent polymeric member. In a specific embodiment, the transparent polymeric member has a surface region, the surface region being substantially flat and uniform. An example of a solar cell has been described in U.S. Ser. Nos. 11/445,933 and 11/445,948 (corresponding respectively to Attorney Docket Nos. 025902-0002100US and 025902-000220US) filed Jun. 2, 2006, which claims priority to U.S. Provisional Patent Ser. No. 60/688,077 filed Jun. 6, 2005 (Attorney Docket No. 025902-000200US), in the name of Kevin R. Gibson, commonly assigned, and hereby incorporated by reference for all purposes. In a preferred embodiment, the solar cell device including the plurality of photovoltaic regions is housed in a package that is sealed. Of course, there can be other variations, modifications, and alternatives.

Referring now to FIG. 18, the method forms an encapsulating material (first layer) 181 overlying a surface of the cover glass. This diagram is merely an example, which should not unduly limit the scope of the claims herein. One of ordinary skill in the art would recognize many variations, alternatives, and modifications. As used herein, the terms “first” and “second” are not intended to be limiting in any manner and are merely be used for reference purposes. The encapsulating material is preferably provided via deposition of a first layer of encapsulating material (e.g., EVA) overlying a top surface of the cover glass. In a specific embodiment, the encapsulating material is suitably a polymer material that is UV stable. As merely an example, the encapsulating material is a thermoplastic polyurethane material such as those called ETIMEX® film from Vistasolar containing Desmopan® film manufactured by Bayer Material Science AG of Germany, but can be others. An alternative example of such an encapsulating material is Elvax® EVA manufactured by DuPont of Delaware USA, but can be others. Alternatively, the material can be polyvinyl butyral (commonly called “PVB”), which is a resin usually used for applications that desire binding, optical clarity, adhesion, toughness and flexibility, and possibly other characteristics. Depending upon the embodiment, PVB is often prepared from polyvinyl alcohol by reaction with butanal. The encapsulating material is preferably cured (e.g., fused or cross-linked) according to a specific embodiment. In a preferred embodiment, the encapsulating material has a desirable optical property. The encapsulating material has a protecting capability to maintain moisture and/or other contaminants away from certain devices elements according to alternative embodiments. The encapsulating material also can be a filler or act as a fill material according to a specific embodiment. In a specific embodiment, the encapsulating material has an index of refraction ranging from about 1.45 and greater. Of course, there can be other variations, modifications, and alternatives. Depending upon the embodiment, the encapsulating material also provides thermal compatibility between different materials that are provided on either side of the encapsulating material.

Referring again to FIG. 18, the method provides a plurality of solar cells 170 including photovoltaic regions. This diagram is merely an example, which should not unduly limit the scope of the claims herein. One of ordinary skill in the art would recognize many variations, alternatives, and modifications. Each of the solar cells include a plurality of photovoltaic regions and/or strips according to a specific embodiment. The method assembles the plurality of solar cells, which are coupled to each other, overlying the layer of encapsulating material to form a multilayered structure. As shown, the optically transparent member serves as an aperture, which couples to aperture regions of the solar cells. In a preferred embodiment, each of the solar cells is aligned to each other via a mechanical self-alignment mechanism, electrically coupling device, or other device that causes a physical location of each of the cells to be substantially fixed in spatial position along a region of the transparent member. The mechanical alignment mechanism may be a portion of the electrical connections on each of the solar cells or other portions of the solar cell depending upon the specific embodiment. In a specific embodiment, the self-alignment mechanism also keys the electrical interconnect such that the polarity between cells is always correct to prevent assembly problems. The self-alignment mechanism is designed into the cells as a “tongue and groove” or notches and nibs, or other configurations. The cells are placed next to each other such that the alignment features interlock with each other. Of course, one of ordinary skill in the art would recognize many variations, modifications, and alternatives.

In a specific embodiment, the present method and structure includes a polymeric coupling material, which can be a double sided tape or like structure. That is, coupling material 181 is the double sided tape. The tape is characterized by a thickness, length, and width according to a specific embodiment. The tape is mechanically solid and includes adhesives on each side according to a specific embodiment. The tape is characterized by a transmittance of about 98% or 99% and greater for wavelengths ranging from about 380 to about 780 nanometers according to a specific embodiment. In a specific embodiment, the tape can be used to mechanically couple the solar cell to the optically transparent member. Depending upon the embodiment, the tape can be used as a coupling material for smooth, textured, or rough surfaces characterizing the optically transparent member. In preferred embodiments, the optically transparent member is smooth to reduce internal reflection. In a specific embodiment, the present method and structure provides the double sided tape coupling material overlying the surface region of the transparent polymeric member. In a specific embodiment, the tape has a haze level of about 1% and less. Additionally, the tape can withstand high temperature, humidity, and UV resistance according to a specific embodiment. The tape is also substantially free from particulate contamination according to a specific embodiment. As merely an example, the double-coated adhesive tape with superior transparency includes HJ-3160W, HJ-9150W Nitto Denko HJ-3160W and HJ-9150W, which are double-coated adhesive tapes that offer superior transparency. In a preferred embodiment, the tapes offer superior transparency, weather resistance and heat resistance, and can be used for bonding transparent materials. Alternatively, the tape product can include 3M™ Optically Clear Adhesive 8141 (or 8141 and the like), which is a 1.0 mil, highly specialized optically clear free-film adhesive offering superior clarity and adhesion capabilities for use in touch screen displays and other applications requiring an optically clear bond manufactured by 3M Company, 3-M Center, St Paul, Minn. 55144. In a preferred embodiment, the tape also provides a final interface that is substantially free from bubbles (e.g., voids), dirt, gels, and other imperfections that may lead to optical distortion. Of course, there can be other variations, modifications, and alternatives.

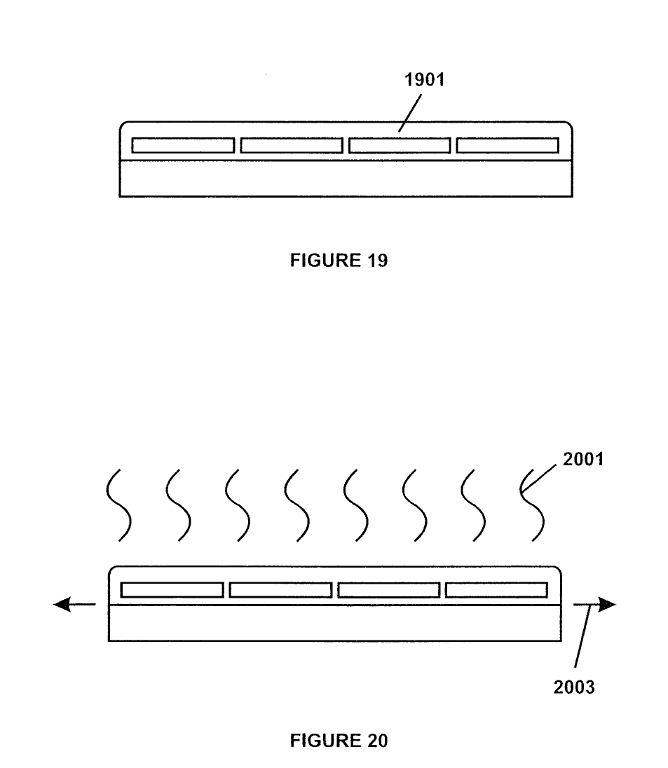

In a specific embodiment, the method forms a second layer 1901 of encapsulating material overlying the plurality of solar cells, as illustrated in the simplified diagram of FIG. 19. The encapsulating material is preferably provided via deposition of the encapsulating material overlying the electrical connections and may also be overlying backside regions of the solar cells depending upon the specific embodiment. In a specific embodiment, the encapsulating material is suitably a silicone pottant that has high electrical insulation, low water absorption, and excellent temperature stability. Other types of materials may include Parylene based materials according to a specific embodiment. As merely an example, the encapsulating material is a pottant material such as those called OR-3100 low viscosity pottant kit from Dow Corning, USA, but can be others. The encapsulating material is preferably cured according to a specific embodiment. As shown, the encapsulant material occupies regions in a vicinity of the electrical connections according to a specific embodiment. Alternatively, the method forms an encapsulating layer overlying the second elastomer material according to a specific embodiment. In other embodiments, the encapsulating material can be a tape structure or other suitable material. Of course, one of ordinary skill in the art would recognize other variations, modifications, and alternatives.

In a specific embodiment, the method includes laminating the multilayered structure using a laminating apparatus, as shown in FIG. 20. This diagram is merely an example, which should not unduly limit the scope of the claims herein. One of ordinary skill in the art would recognize many variations, alternatives, and modifications. That is, the multilayered structure is subjected to suitable conditions and processes for lamination to occur, which essentially bonds the layers together according to a specific embodiment. As merely an example, the optical coupling material and/or sheets should be processed at a temperature of about 170 Degrees Celsius and less or 150 Degrees Celsius to laminate the coupling material without damaging the packaged polymeric package structure of the solar cell according to a specific embodiment. As shown, each of the solar cells becomes substantially fixed onto surfaces of the transparent member according to a specific embodiment. In a specific embodiment, the lamination process includes a thermal treatment and application of vacuum on the optical material structure including packaged solar cell to laminate the upper and lower coupling materials with the packaged solar cell device therein. Of course, one of ordinary skill in the art would recognize many variations, modifications, and alternatives.

In a specific embodiment, the method includes forming electrical connections between one or more of the solar cells. That is, each of the solar cells may be coupled to each other in series and/or parallel depending upon a specific embodiment. In a preferred embodiment, the method couples the solar cells together in series from a first solar cell, a second solar cell, and an Nth solar cell, which is the last solar cell on the panel assembly. The first electrical connection of one cell is connected to the second electrical connection of next cell in series. In a preferred embodiment the electrical connection is made by attaching a wire or metal strip across the first and second electrical connections of adjacent cells. The wire or metal strip is then soldered at both ends to the cells' electrical connections. Alternatively, other processes such as using electrically conducting epoxies or adhesives to attach the wire or metal strip to the cells' electrical connections could be used. Of course, one of ordinary skill in the art would recognize many variations, modifications, and alternatives.

In a specific embodiment, the method assemblies one or more junction boxes onto portions of the electrical interconnects. The method also attaches one or more frame members onto edges or side portions of the optically transparent member including the plurality of solar cells. In a specific embodiment, the junction box is used to electrically connect the module to other modules or to the electrical load. The junction box contains connection terminals for the external wires and connection terminals for the internal electrical leads to the cells in the module. The junction box may also house the bypass diode used to protect the module when it is shaded. The junction box is placed on the back or side of the module such that connections to the first and last cells in the interconnected series of cells is easily accessible. The junction box is attached and sealed to the module using RTV silicon. Electrical connections are made through soldering, screw terminals, or as defined by the junction box manufacturer. As merely an example, the SOLARLOK™ interconnect system from Tyco Electronics could be used to provide the junction box and interconnects, but can be others. The module frame is attached to the sides of the module to provide for easy mounting, electrical grounding, and mechanical support. In a preferred embodiment, the frames are made from extruded aluminum cut to length. Two lengths would have counter-sunk holes to provide for screw passage. The remaining two lengths would have predrilled or hollow area for the screws to fasten. The extruded aluminum would contain channels designed to capture the laminate. A foam strip is placed around the edges of the module and then the extruded aluminum channel is pressed over the foam. When all four sides are properly located, two screws at each corner are inserted to hold the frame together. In an alternate embodiment, the frame could be provided by a molded polymer with or without a metal support structure, As shown, the present method forms a resulting structure that may exposed certain backside regions of the solar cells, which are characterized by sealed backside regions, according to specific embodiments. Of course, one of ordinary skill in the art would recognize many variations, modifications, and alternatives.

The above sequence of steps provides a method according to an embodiment of the present invention. As shown, the method uses a combination of steps including a way of forming a solar panel, which has a plurality of solar cells using regions of photovoltaic material. Other alternatives can also be provided where steps are added, one or more steps are removed, or one or more steps are provided in a different sequence without departing from the scope of the claims herein.

In a specific embodiment, the present solar cell panel is substantially sealed to prevent undesirable moisture from contacting one or more elements of the solar cell device. In a specific embodiment, the sealed solar cell including the single or multiple sealed structures prevents excessive moisture from entering and contacting one or more elements (e.g., contacts, bus bars, photovoltaic regions), which can lead to corrosion that leads to undesirable effects, e.g., short circuits, opens, mechanical degradation, electrical degradation. In a preferred embodiment, the one or more elements within the sealed solar cell is substantially free from moisture, which may be in a liquid state or vapor state. In other embodiments, the moisture (e.g., water) may lead to a reduction of concentration provided by one or more concentrating elements, which couple to one or more respective photovoltaic regions. Of course, there can be other variations, modifications, and alternatives.

In alternative specific embodiments, the present solar cell device and panel can include a dessicant provided therein. In a specific embodiment, the dessicant can be any suitable material such as silica material, or the like. As merely an example, a commercial moisture getter material can include a product called STAYDRY™ SD1000 from Cookson Semiconductor Packaging Materials, but can be others. In a specific embodiment, the dessicant can be coated within one or more elements within the solar cell. Alternatively, the dessicant can be provided within one or more regions of the solar cell. Alternatively, the dessicant can be provided within a vicinity of an interface region of the solar cell. In a preferred embodiment, the dessicant captures moisture that may lead to corrosion within the solar cell device. Of course, there can be other variations, modifications, and alternatives.

In a yet alternative specific embodiment, the present invention provides a method for manufacturing a solar panel using assembly process, which can be used in volume manufacturing. An outline of the method can be provided below.

1. Provide a first sealed solar cell (as used herein, the term “first” is not intended to be limiting and should be interpreted by its ordinary meaning;

2. Align the first sealed solar cell to at least a pair of first electrical contact members coupled to respective first and second bus bar members provided on a base substrate member (e.g., printed circuit board, substrate member with contacts and electrodes);

3. Electrically couple the first sealed solar cell to the pair of first and second bus bar members;

4. Provide a second sealed solar cell (as used herein, the term “second” is not intended to be limiting and should be interpreted by its ordinary meaning);

5. Align the second sealed solar cell to at least a pair of second electrical contact members coupled to respective first and second bus bar members provided on the base substrate member;

6. Electrically couple the second sealed solar cell to the pair of the first and second bus bar members according to a specific embodiment;

7. Optionally, replace the first and/or second sealed solar cells with a third sealed solar cell or the third sealed solar cell and a fourth sealed solar cell;

8. Perform other steps, as desired.

The above sequence of steps provides a method according to an embodiment of the present invention. As shown, the method uses a combination of steps including a way of forming a solar panel, which has a plurality of solar cells using regions of photovoltaic material. In a preferred embodiment, the solar cells are disposed onto a target substrate, which has contact regions. Other alternatives can also be provided where steps are added, one or more steps are removed, or one or more steps are provided in a different sequence without departing from the scope of the claims herein. Further details of the present method and resulting structures can be found throughout the present specification and more particularly below.

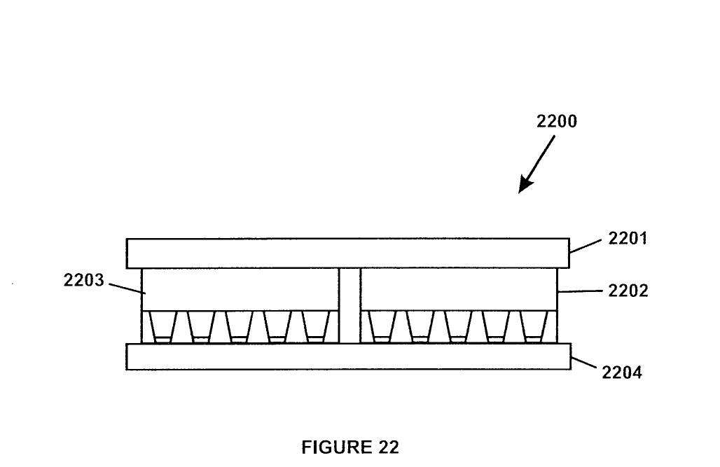

FIGS. 22 through 24 are simplified diagrams of assembling one or more solar cells onto a target board according to embodiments of the present invention. These diagrams are merely examples, which should not unduly limit the scope of the claims herein. One of ordinary skill in the art would recognize other variations, modifications, and alternatives.

FIG. 22 illustrates a side view of a solar cell assembly 2200 according to an embodiment of the present invention. This diagram is merely an example, which should not unduly limit the scope of the claims. One of ordinary skill in the art would recognize many variations, alternatives, and modifications. As shown, the solar cell assembly 2200 includes a transparent member 2201 overlaying sealed solar cells 2202 and 2203. For example, each of the sealed solar cells include concentrators coupled respectively to photovoltaic strips such as those described throughout the present specification. Depending upon application, the transparent member 2201 may consist of a variety of materials, such as polymer, glass, multilayered materials, combinations of these, and the like. The transparent member 2201 is coupled to the sealed solar cells 2202 and 2203 according to a specific embodiment.

As an example, the transparent member 2201 may be coupled to the sealed solar cells 2202 and 2203 in a number of ways. In a specific embodiment, the transparent member is coupled to each of the solar cells using an optical coupling material. Examples of optical coupling materials, including double sided tape, have been described throughout the present specification. Of course, there can be other variations, modifications, and alternatives. Depending upon the embodiment, each of the sealed solar cells can be treated to enhance adherence and/or optical coupling between the transparent member and surface region coupling each of the concentrator members. Further details of such treatment can be found throughout the present specification and more particularly below.

According to a specific embodiment, the solar cell assembly 2200 includes an adhesion promoter and/or enhancer provided on an upper surface of the sealed solar cells 2202 and 2203, which couples to transparent member 2201. As an example, the adhesion promoter can be any suitable substance and/or substances known by one of ordinary skill in the art. The adhesion promoter can be provided on the surface that couples to a transparent optical coupling material, which also couples to the transparent member 2201. In a preferred embodiment, the adhesion promoter is optically transparent and can act as a glue and/or barrier layer between the sealed solar cells 2202 and 2203 and the optical coupling material. Of course, there can be other variations modifications, and alternatives.

In another specific embodiment, the solar cell assembly 2200 includes surface texturing of the upper surface of the transparent member 2201, which couples to the transparent glass plate. In one or more embodiments, the surface texture can also be used with the adhesion promoter that has been previously described. The surface can be textured in a suitable manner that enhances adhesion between the transparent member and optical coupling material according to a specific embodiment. Depending upon the embodiment, the texture can be a pattern or patterns or other surface characteristics such as changes in spatial features, e.g., roughness, designs. In a preferred embodiment, the textured and/or patterned surface is generally optically transparent and can cause enhancement of the attachment between the transparent polymer member and the optical coupling material. Of course, there can be other variations, modifications, and alternatives.

Now referring back to FIG. 22, the sealed solar cells 2202 and 2203 are attached to a target board 2204. The sealed solar cells 2202 and 2203 may be attached to the target board 2204 in a number of ways. In a specific embodiment, the sealed solar cells are placed onto the target board using any suitable connection devices. Such connection devices can include sockets, solder bumps, pins, contact pads, mechanical probe devices, any combination of these, and the like. According to an example, the sealed solar cells 2202 and 2203 are fitted into the target board 2204 using one or more of these techniques. According to another example, the sealed solar cells 2202 and 2203 are glued to the target board 2204 using an adhesive or other suitable attachment technique. Of course, there can be other variations, modifications, and alternatives.

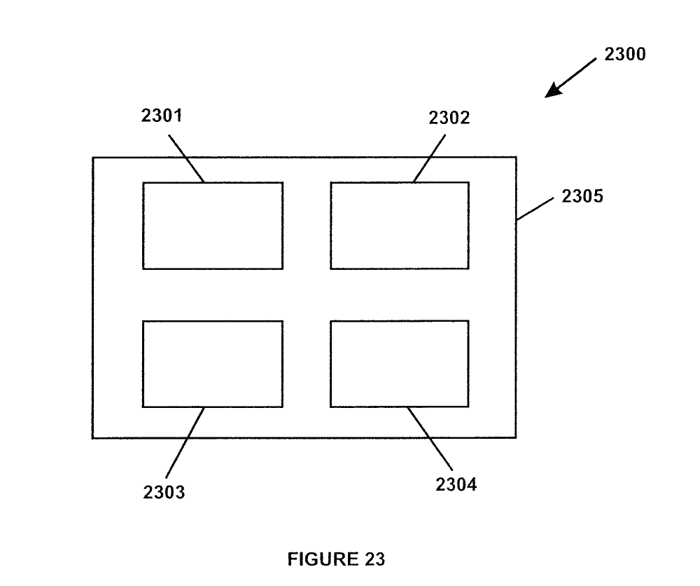

FIG. 23 illustrates a top view of a solar cell assembly 2300 according to an embodiment of the present invention. According to an example, solar cells 2201-2204 are attached to a target board 2305. As shown, the solar cells 2201-2204 are aligned to form a rectangular shape. It is to be understood that various alignments may be used. For example, solar cells may be in an annular, trapezoidal, square, or hexagonal shape and aligned in honeycomb shape. For example, solar energy gathered by each of solar cells are transferred and via the target board 2305 according to a specific embodiment.

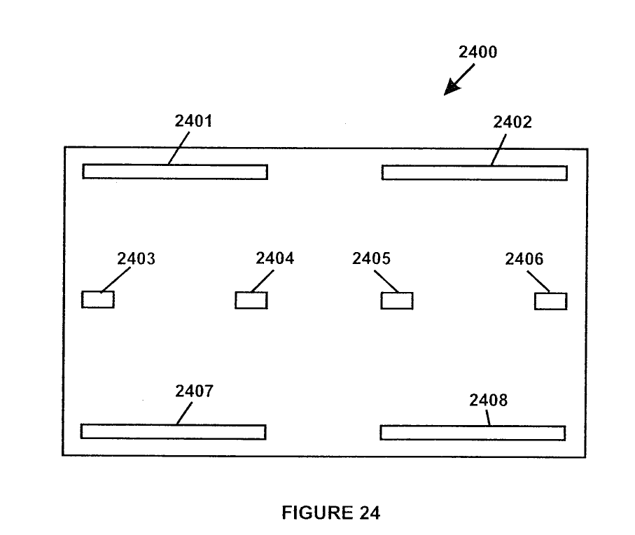

FIG. 24 illustrates a top view of a target board 2305. Depending upon application, various materials and design may be used to implement the target board 2305. According to an example, the target board 2305 is a print circuit board, which includes one or more interconnect structures. As shown, the target board 2305 includes mechanical alignment guides 2401, 2402, 2407, and 2408. For example, the alignment guides guide solar cells to be properly positioned. As another example, the alignment guides can also be used to electrically connect the solar cells to the target boards. According to certain embodiments, the target board 2305 includes different configurations for alignment guides for specific applications.

According to an embodiment, the target board 2305 also provides connectors 2403-2406, e.g., metal electrodes, copper electrodes, aluminum electrodes. Depending upon applications, the connectors may be utilized to provide physical and/or electrical connections. According to an embodiment, the connectors provides electrical contacts and the target board 2305 includes electrical wiring beneath the connectors. According to another embodiment, the connectors are sockets that allows solar cells to snap into the connectors. Alternatively, the target board can include pin holes, recessed regions (for electrical and mechanical support and connection), solder bumps, contact pads (e.g., solder, gold plated, silver plated, copper), insertion structures, any combination of these, and the like. It is to be understood that various embodiments of the present invention provides various ways for solar cell packaging. Further details of ways of manufacturing the solar panel can be found throughout the present specification and more particularly below.

In still a further embodiment, the present invention provides a method for manufacturing a solar panel, e.g., module. The method includes providing a first sealed solar cell. As used herein, the term “first” is not intended to be limiting and should be interpreted by its ordinary meaning. The method includes aligning the first sealed solar cell to at least a pair of first electrical contact members coupled to respective first and second bus bar members provided on a base substrate member, which can be the target board described above. The method includes electrically coupling the first sealed solar cell to the pair of first and second bus bar members. The method also includes providing a second sealed solar cell. As used herein, the term “second” is not intended to be limiting and should be interpreted by its ordinary meaning. In a specific embodiment, the method includes aligning the second sealed solar cell to at least a pair of second electrical contact members coupled to respective first and second bus bar members provided on the base substrate member. The method also includes electrically coupling the second sealed solar cell to the pair of the first and second bus bar members according to a specific embodiment. Depending upon the embodiment, the contact members can include a pair of solder bumps, one or more sockets, one or more pins, one or more leads, or any other suitable conduction members, and the like. In alternative embodiments, the first and/or second sealed solar cells can be replaced. That is, the method includes removing either or both the first sealed solar cell or the second sealed solar cell from the substrate member; and replacing either or both the first sealed solar cell or the second sealed solar cell with a third sealed solar cell or the third sealed solar cell and a fourth sealed solar cell. Of course, there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims. That is, the present panel structure includes a solar cell with a concentrating element provided thereon. Such concentrating element or elements may be provided (e.g., integrated) on a cover glass of the solar panel according to a specific embodiment. In a specific embodiment, an example of a solar cell that can be used in the present module and method has been described in U.S. Ser. Nos. 11/445,933 and 11/445,948 (corresponding respectively to Attorney Docket Nos. 025902-0002100US and 025902-000220US) filed Jun. 2, 2006, which claims priority to U.S. Provisional Patent Ser. No. 60/688,077 filed Jun. 6, 2005 (Attorney Docket No. 025902-000200US), in the name of Kevin R. Gibson, commonly assigned, and hereby incorporated by reference for all purposes. In one or more embodiments, each of the photovoltaic strips is coupled to a concentrator element, which can be together a separate stand alone unit (e.g., one concentrator coupled to one strip). The stand alone unit can include contact regions that are electrically coupled to bus regions of a target substrate. Of course, there can be other variations, modifications, and alternatives.

1-58. (canceled)

59. A method for manufacturing a solar panel, the method comprising:
providing a first sealed solar cell, the first sealed solar cell comprising a first transparent polymeric member, the first transparent polymeric member comprising one or more first photovoltaic regions coupled to the first transparent polymeric member, the one or more first photovoltaic regions occupying at least about 10% of a first aperture surface region of the first transparent polymeric member and up to about 100% of the first aperture surface region of the first transparent polymeric member, the first transparent polymeric member comprising a first surface region, the first surface region being substantially flat and uniform, the one or more first photovoltaic regions being first sealed between the first transparent polymeric member and a first backside member;
aligning the first sealed solar cell to at least a pair of first electrical contact members coupled to respective first and second bus bar members provided on a base substrate member;
electrically coupling the first sealed solar cell to the pair of first and second bus bar members;
providing a second sealed solar cell, the second sealed solar cell comprising a second transparent polymeric member, the second transparent polymeric member comprising one or more second photovoltaic regions coupled to the second transparent polymeric member, the one or more second photovoltaic regions occupying at least about 10% of a second aperture surface region of the second transparent polymeric member and up to about 100% of the second aperture surface region of the second transparent polymeric member, the second transparent polymeric member comprising a second surface region, the second surface region being substantially flat and uniform, the one or more second photovoltaic regions being second sealed between the second transparent polymeric member and a second backside member;
aligning the second sealed solar cell to at least a pair of second electrical contact members coupled to respective first and second bus bar members provided on the base substrate member; and
electrically coupling the second sealed solar cell to the pair of the first and second bus bar members.

60. The method of claim 59 wherein the contact members comprises a pair of solder bumps.

61. The method of claim 59 wherein the first contact members comprise a first socket member coupled to the substrate member and the second socket members comprise a second socket member coupled to the substrate member.

62. The method of claim 59 further comprising removing either or both the first sealed solar cell or the second sealed solar cell from the substrate member; and replacing either or both the first sealed solar cell or the second sealed solar cell with a third sealed solar cell or the third sealed solar cell and a fourth sealed solar cell.

63-75. (canceled)

76. A solar panel comprising:
a target board, the target board including a surface region and at least a first bus bar and a second bus bar, the surface region including at least a first pair of contact members and a second pair of contact members;
a first sealed solar cell coupled to at least the first bus bar and the second bus bar via the first pair of contact members, the first sealed solar cell comprising a first transparent polymeric member, the first transparent polymeric member comprising one or more first photovoltaic regions coupled to the first transparent polymeric member, the one or more first photovoltaic regions occupying at least about 10% of a first aperture surface region of the first transparent polymeric member and up to about 100% of the first aperture surface region of the first transparent polymeric member, the first transparent polymeric member comprising a first surface region, the first surface region being substantially flat and uniform, the one or more first photovoltaic regions being first sealed between the first transparent polymeric member and a first backside member; and
a second sealed solar cell coupled to at least the first bus bar and the second bus bar via the second pair of contact members, the second sealed solar cell comprising a second transparent polymeric member, the second transparent polymeric member comprising one or more second photovoltaic regions coupled to the second transparent polymeric member, the one or more second photovoltaic regions occupying at least about 10% of a second aperture surface region of the second transparent polymeric member and up to about 100% of the second aperture surface region of the second transparent polymeric member, the second transparent polymeric member comprising a second surface region, the second surface region being substantially flat and uniform, the one or more second photovoltaic regions being second sealed between the second transparent polymeric member and a second backside member.

77. The panel of claim 76 wherein the first pair of contact members comprise a first pair of sockets and the second pair of contact members comprise a second pair of sockets.

78. The panel of claim 76 wherein the first pair of contact members comprise a first pair of contact regions and the second pair of contact members comprise a second pair of contact regions.
